(19) United States
(12) Patent Application Publication
(10) Pub. No.: US 2010/0266959 A1
(43) Pub. Date: Oct. 21, 2010

(54) Pattern forming method

(76) Inventors: Sang-Hee Lee, Yongin-si (KR); Jin Choi, Seoul (KR); Byung-Gook Kim, Seoul (KR); Hee-Bom Kim, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 12/662,402

(22) Filed: Apr. 15, 2010

(30) Foreign Application Priority Data
Apr. 16, 2009 (KR) 10-2009-0033232

(51) Int. Cl. G03F 7/20

(52) U.S. Cl. 430/296

(57) ABSTRACT

A pattern forming method includes providing a resist, irradiating a first electron beam to a first region of the resist, and irradiating a second electron beam to a second region which is defined along a boundary of the first region of the resist, wherein the first electron beam has a first cross section having a polygonal shape, and the second electron beam has a second cross section having a polygonal shape.

### BACKGROUND

1. Field

Example embodiments relate to forming patterns, and more particularly, to a method of forming patterns of a mask, which is used in a semiconductor process, by using an electron beam writer.

2. Description of the Related Art

As semiconductor devices become more highly integrated, the width of patterns formed on a substrate and gaps between the patterns are increasingly reduced. Accordingly, this has led to the development of various lithographic technologies for forming patterns. Conventional reduction projection lithography using ultraviolet light, however, has limitations in forming patterns of a semiconductor device which have fine design rules. Thus, attempts have been made to use electron beam lithography using an electron beam to form fine patterns.

Electron beam lithography using an electron beam is a technology for forming a material layer on an entire surface of a substrate and patterning the material layer in a desired shape. That is, the material layer is coated with a resist, and desired resist patterns are written on the resist with an electron beam. Then, the resist is developed, and the material layer is etched using the resist patterns as a mask.

Electron beam lithography can be used to form predetermined material layer patterns, which form an integrated circuit, directly on a substrate. However, it is generally used to fabricate photomasks used in photolithography.

### SUMMARY

Embodiments are therefore directed to a pattern forming method, which substantially overcomes one or more of the problems due to the limitations and disadvantages of the related art.

It is therefore a feature of an embodiment to provide a pattern forming method which does not distort a critical dimension (CD) design value by minimizing scattering of an electron beam.

At least one of the above and other features and advantages may be realized by providing a pattern forming method, including providing a resist, irradiating a first electron beam to a first region of the resist, and irradiating a second electron beam to a second region which is defined along a boundary of the first region of the resist, wherein the first electron beam has a first cross section having a polygonal shape, and the second electron beam has a second cross section having a polygonal shape.

Irradiating the first electron beam may include emitting a first pre-electron beam, and passing the first pre-electron beam sequentially through a first mask having a first aperture and a second mask having a second aperture to form the first electron beam, an overlap region of the first aperture and the second aperture having a polygonal shape. The polygonal shape of the overlap region may be a square or a triangle. Irradiating the second electron beam may include emitting a second pre-electron beam, and passing the second pre-electron beam sequentially through the first mask having the first aperture, the second mask having the second aperture, and a third mask to form the second electron beam, the third mask and the overlap region partially overlapping each other. At least one side of the polygonal shape of the overlap region and at least one side of the third mask may be parallel to each other. The first through third masks may be made of insulating materials. The second region of the resist may be within the first region of the resist. The second region of the resist may be narrower than the first region of the resist. Irradiating the first and second electron beams may include irradiating the second electron beam at a higher intensity than the first electron beam.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic diagram of an electron beam writer used in example embodiments;

FIG. 2 illustrates a diagram of a first mask of the electron beam writer used in example embodiments;

FIG. 3 illustrates a diagram of a second mask of the electron beam writer used in example embodiments;

FIG. 4 illustrates a diagram of the first and second masks overlapping each other;

FIG. 5 illustrates a diagram of a square cross section of a first electron beam;

FIG. 6 illustrates a diagram of the first and second masks overlapping each other;

FIG. 7 illustrates a diagram of a triangular cross section of the first electron beam;

FIGS. 8 and 9 illustrate diagrams of a second electron beam formed when the cross section of the first electron beam is square;

FIGS. 10 and 11 illustrate diagrams of the second electron beam formed when the cross section of the first electron beam is triangular;

FIG. 12 illustrate a cross-sectional diagram of a substrate on which a resist is formed;

FIG. 13 illustrate a diagram of irradiation of the first electron beam; and

FIG. 14 illustrates a diagram of irradiation of the second electron beam.

### DETAILED DESCRIPTION

Korean Patent Application No. 10-2009-0033232, filed on Apr. 16, 2009, in the Korean Intellectual Property Office, and entitled: “Pattern Forming Method,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that, although the terms first, second, third, etc., may be used herein to describe various elements, components and/or sections, these elements, components and/or sections should not be limited by these terms. These terms are only used to distinguish one element, component or section from another element, component or section. Thus, a first element, component or section discussed below could be termed a second element, component or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Spatially relative terms, such as “below,” “beneath,” “lower,” “above,” “upper,” and the like, may be used herein for ease of description to describe one device or element's relationship to another device(s) or element(s) as illustrated in the drawings. It will be understood that the spatially relative terms are intended to encompass different orientations of the device in use or operation in addition to the orientation depicted in the drawings. For example, if the device in the figures is turned over, elements described as “below” or “beneath” other elements or features would then be oriented “above” the other elements or features. Thus, the exemplary term “below” can encompass both an orientation of above and below. The device may be otherwise oriented and the spatially relative descriptors used herein interpreted accordingly.

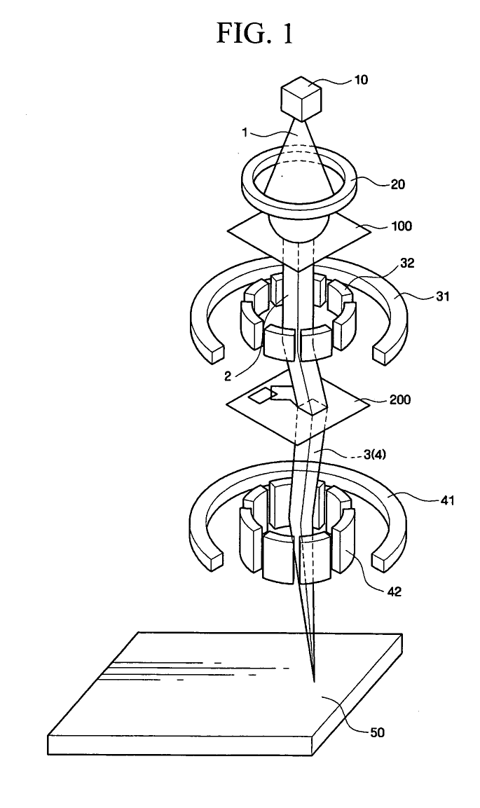

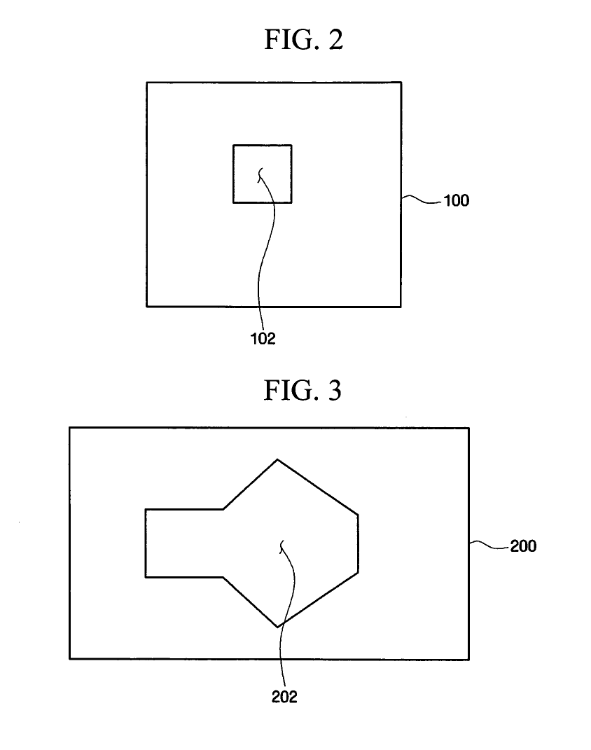

Hereinafter, a variable shaped beam (VSB) electron beam writer (hereinafter, referred to as an ‘electron beam writer’) used in a pattern forming method according to an exemplary embodiment will be described with reference to FIGS. 1 through 3. FIG. 1 illustrates a schematic diagram of an electron beam writer used in example embodiments. FIG. 2 illustrates a diagram of a first mask 100 of the electron beam writer used in example embodiments. FIG. 3 illustrates a diagram of a second mask 200 of the electron beam writer used in example embodiments.

Referring to FIG. 1, the electron beam writer may include an electron gun 10, the first mask 100, a projection lens 31, a shaping deflector 32, the second mask 200, an objective lens 41, a main deflector 42, and a stage 50.

The electron gun 10 generates an electron beam using electron current. The electron gun 10 passes hot electrons from a cathode through one or more donut-shaped electrodes with a hole in the middle, thereby focusing the hot electrons. Then, the electron gun 10 emits the focused hot electrons in the form of a beam. Here, the focused hot electrons are accelerated at high speed.

An electron beam emitted from the electron gun 10 may pass through a condenser lens 20. The condenser lens 20 may concentrate the electron beam onto a first aperture 102 (see FIG. 2) of the first mask 100.

In detail, the electron beam emitted from the electron gun 10 may be spread at an angle by a repulsive force between electrons that form the electron beam. Accordingly, in order to avoid loss of part of the electron beam as the electron beam passes through the first aperture 102 of the first mask 100, the electron beam may be concentrated by the condenser lens 20 to prevent or substantially minimize loss of electrons when the electron beam passes through the first aperture 102.

The condenser lens 20, which concentrates the electron beam, may include an electromagnet. When an electric field is applied to the electron beam by the electromagnet, an electromagnetic force of the electric field concentrates the electron beam. That is, when a negative electromagnetic force greater than the repulsive force between the electrons of the electron beam is applied to the electron beam, a repulsive force is created between the negative electromagnetic force and the electron beam. This repulsive force concentrates the electron beam.

The electron beam concentrated by the condenser lens 20 may pass through the first aperture 102 in the first mask 100. When emerging from the first aperture 102, the electron beam may have a polygonal cross section.

The first mask 100 may be made of an insulating material in order to eliminate an electromagnetic effect between itself and the electron beam.

The first aperture 102 formed in the first mask 100 may be polygonal. For example, the first aperture 102 shown in FIG. 2 is square. However, the shape of the first aperture 102 is not limited to the square shape. The first aperture 102 may have triangular, pentagonal, hexagonal, or other polygonal shapes.

The cross-sectional shape of the electron beam that passes through the first aperture 102 may be determined by the shape of the first aperture 102. For example, when the first aperture 102 is square as shown in FIG. 2, the electron beam that passes through the first aperture 102 may have a square cross section. When the shape of the first aperture 102 is triangular, the electron beam that emerges from the first aperture 102 may have a triangular cross section.

The electron beam that passes through the first mask 100 may travel through the projection lens 31 and the shaping deflector 32. The projection lens 31 and the shaping deflector 32 may change the path of the electron beam.

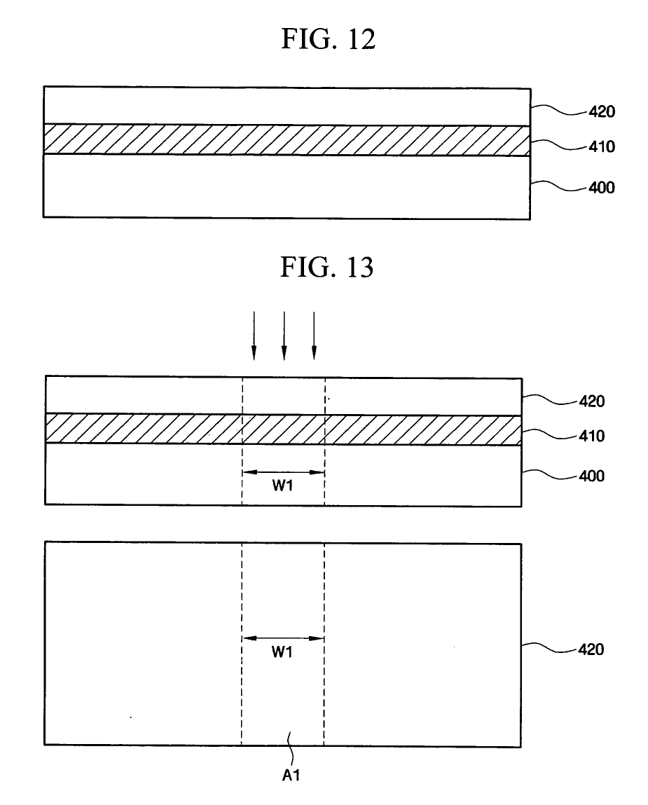

That is, the projection lens 31 and the shaping deflector 32 may change the path of the electron beam, such that the electron beam proceeds to a predetermined region of a resist 420 (see FIG. 12) which is to be irradiated with the electron beam. Each of the projection lens 31 and the shaping deflector 32 may include an electromagnet. Thus, the projection lens 31 and the shaping deflector 32 may apply an electric field to the electron beam. When an electric field is applied to the electron beam, an electromagnetic force of the electric field changes the path of the electron beam, such that the electron beam travels in a predetermined direction.

The electron beam that passes through the projection lens 31 and the shaping deflector 32 may travel through the second mask 200. Here, the electron beam may pass through a second aperture 202 formed in the second mask 200. When emerging through the second aperture 202, the electron beam may have a polygonal cross section.

The second mask 200 may be made of an insulating material in order to eliminate the electromagnetic effect between itself and the electron beam.

The second aperture 202 formed in the second mask 200 may be polygonal. For example, the second aperture 202 may have a polygonal shape shown in FIG. 3. However, the shape of the second aperture 202 is not limited to the polygonal shape shown in FIG. 3.

When the electron beam passes sequentially through the first aperture 102 of the first mask 100 and the second aperture 202 of the second mask 200, a final shape of the electron beam, i.e., a shape to be irradiated to the resist 420, may be defined.

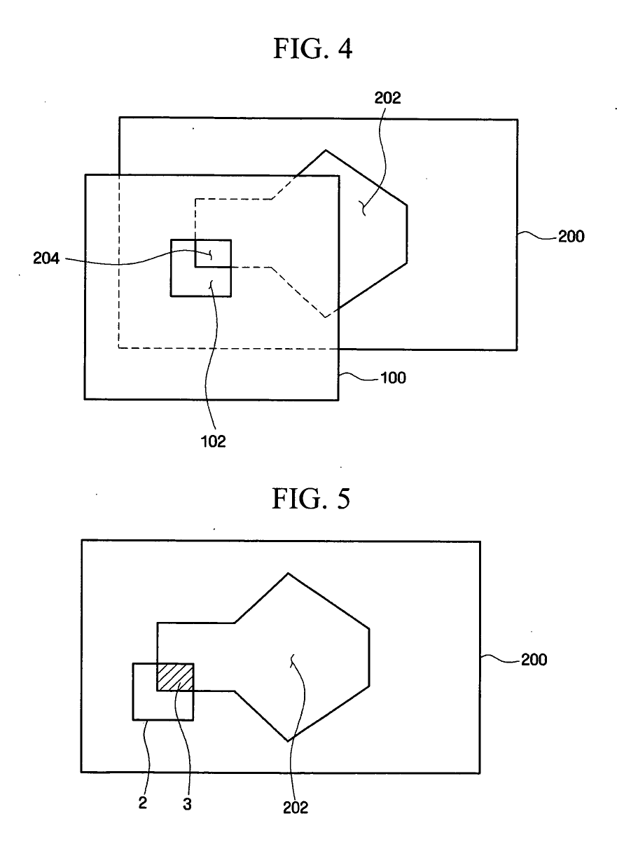

To make the electron beam have a cross-sectional shape identical to a shape of a pattern to be formed, the second mask 200 may rotate about a virtual axis which corresponds to the direction of the electron beam. In addition, the second mask 200 may move in a direction parallel to the direction of the electron beam or in a direction parallel to a direction which is perpendicular to the direction of the electron beam. To this end, the electron beam writer may include a second mask driver (not shown). A detailed description of adjusting a shape of the electron beam to be irradiated onto the resist 420 will be described in more detail below with reference to FIGS. 4-11.

The electron beam that passes through the second mask 200 may travel through the objective lens 41 and the main deflector 42 before being irradiated to the resist 420.

The objective lens 41 and the main deflector 42 may reduce the size of the electron beam that is to be irradiated to the resist 420. This is to match a designed pattern (such as the circuit linewidth) with a resist pattern that is to be formed by irradiation of the electron beam. The objective lens 41 and the main deflector 42 may adjust the cross-sectional width of the electron beam to a desired linewidth of a semiconductor circuit, e.g., a linewidth of several nm to several pm. In addition, the objective lens 41 and the main deflector 42 may change the path of the electron beam, such that the electron beam may reach a region of the resist 420 in which a pattern is to be formed.

The objective lens 41 may include an absorption plate (not shown). The absorption plate may be installed on a bottom surface of the objective lens 41. The absorption plate may reduce rescattering of an irradiated electron beam, thereby ensuring formation of a high-resolution pattern.

An object on which a pattern is to be formed may be placed on the stage 50. For example, an object having a resist on a substrate may be placed on the stage 50. The stage 50 may move along X and/or Y axis during a pattern forming process. Since the object is moved by the stage 50, various patterns can be formed on the object even if the path of the electron beam is fixed in one direction.

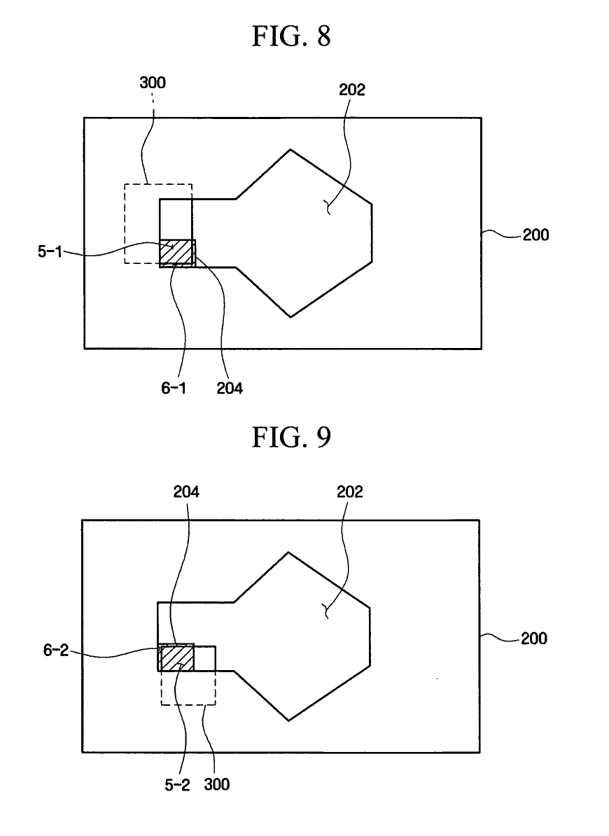

Although not shown in FIG. 1, the electron beam writer used in example embodiments may further include a third mask 300 (see FIG. 8). The third mask 300 may be disposed under the second mask 200, e.g., the third mask 300 may be between the second mask 200 and the stage 50. The third mask 300 will be described in detail later.

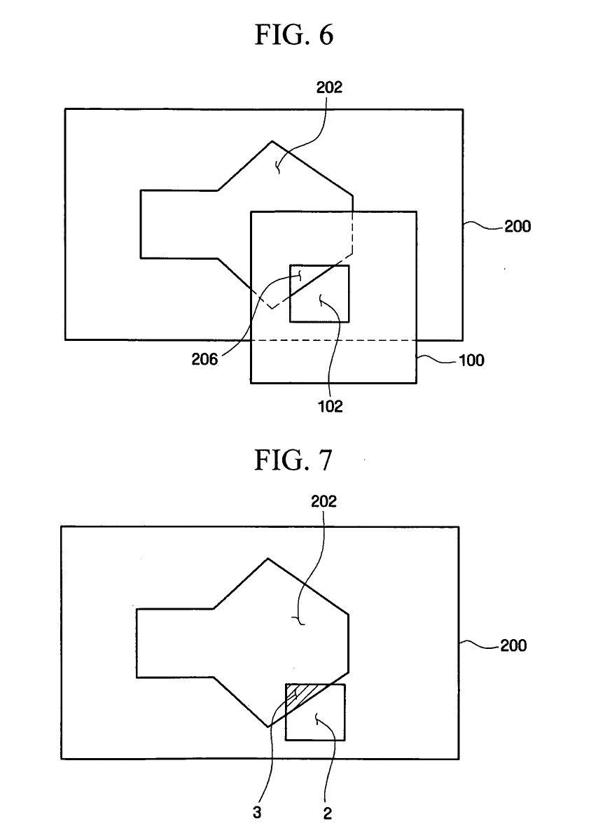

The process of forming a first electron beam in a pattern forming method according to an exemplary embodiment will now be described with reference to FIGS. 1 and 4 through 7. FIGS. 4 and 6 illustrate diagrams of the first and second masks 100 and 200 overlapping each other. FIG. 5 illustrates a diagram of a square cross section of a first electron beam 3. FIG. 7 illustrates a diagram of a triangular cross section of the first electron beam 3.

Referring to FIGS. 1 and 4, the first and second masks 100 and 200 may be positioned in the electron beam writer to overlap each other. Accordingly, the first aperture 102 of the first mask 100 may partially overlap the second aperture 202 of the second mask 200, thereby forming a first overlap region 204.

For example, the first overlap region 204 shown in FIG. 4 may have a square shape. However, the shape of the first overlap region 204 is not limited to the square shape. That is, the first overlap region 204 may have various polygonal shapes, e.g., positions of the first and second masks 100 and 200 may be adjusted to provide a first overlap region 204 with a desired shape.

For example, the first overlap region 204 needed for design of a pattern may be formed by moving the second mask 200 while the first mask 100 remains stationary. In another example, the first overlap region 204 may be formed by sequentially or simultaneously moving the first and second masks 100 and 200.

Referring to FIGS. 1 and 5, a first pre-electron beam 1 denotes an electron beam emitted from the electron gun 10, i.e., an electron beam before passing through the first mask 100, and a second pre-electron beam 2 denotes the electron beam after passing through the first mask 100 and before passing through the second mask 200. That is, the first pre-electron beam 1 emitted from the electron gun 10 may pass through the condenser lens 20 and then into the first aperture 102 of the first mask 100, and the second pre-electron beam 2 may emerge from the first aperture 102 of the first mask 100 to travel through the second aperture 202 of the second mask 200.

As the first pre-electron beam 1 passes through the first aperture 102, its cross-sectional shape becomes identical to the shape of the first aperture 102. That is, referring to FIGS. 4 and 5, when the first aperture 102 is square, the cross section of the second pre-electron beam 2 that emerges from the first aperture 102 may be square.

The second pre-electron beam 2 that emerges from the first aperture 102 may proceed toward the second mask 200. Here, a first portion of the second pre-electron beam 2, i.e., a portion of the beam reaching the first overlap region 204 of the second mask 200, may pass through the second mask 200. A second portion of the second pre-electron beam 2, i.e., a remaining portion of the beam reaching regions of the second mask 200 other than the first overlap region 204, may fail to pass through the second mask 200.

Consequently, the first portion of the second pre-electron beam 2, which passes through the first overlap region 204 of the second mask 200, may define a first electron beam 3 (a hatched area in FIG. 5). Referring to FIG. 5, since the first overlap region 204 is square, the first electron beam 3 formed after the second pre-electron beam 2 passes through the first overlap region 204 has a square cross section. If the first overlap region 204 has a polygonal shape other than square, the first electron beam 3 formed after the second pre-electron beam 2 passes through the first overlap region 204 may have a corresponding polygonal cross section.

Referring to FIGS. 1 and 6, the first and second masks 100 and 200 may be adjusted to overlap each other at a location different from the location of FIG. 4. For example, the first and second masks 100 and 200 may be adjusted to define a second overlap region 206 having a different shape from the first overlap region 204 of FIG. 4. For example, as illustrated in FIG. 6, the second overlap region 206 may have a triangular shape.

Referring to FIGS. 1 and 7, the second pre-electron beam 2 that emerges from the first aperture 102 of the first mask 100 may travel through the second aperture 202 of the second mask 200. In detail, the first pre-electron beam 2 that emerges from the first aperture 102 may proceed to the second mask 200, so the first portion of the second pre-electron beam 2, i.e., a portion reaching the second overlap region 206 of the second mask 200, may pass through the second mask 200. The second overlap region 206 is a region of the second aperture 202. The second portion of the second pre-electron beam 2, i.e., a remaining portion of the beam reaching regions of the second mask 200 other than the second overlap region 206, may fail to pass through the second mask 200.

Consequently, the portion of the second pre-electron beam 2, which passes through the second overlap region 206 of the second mask 200, may define a first electron beam 3 (a hatched area in FIG. 7) which has a different cross-sectional shape from the first electron beam 3 shown in FIG. 5. Referring to FIG. 7, since the second overlap region 206 is triangular, the first electron beam 3 emerging from the second overlap region 206 may have a triangular cross section.

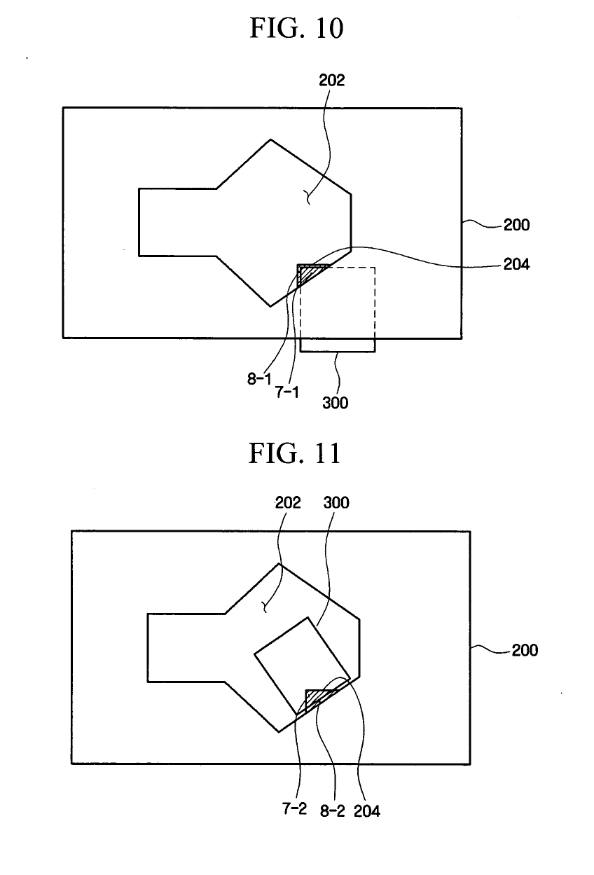

A process of forming a second electron beam in a pattern forming method according to an exemplary embodiment will now be described with reference to FIGS. 1 and 8 through 11. FIGS. 8 and 9 illustrate diagrams of a second electron beam 4 formed when the cross section of the first electron beam 3 is square. FIGS. 10 and 11 illustrate diagrams of a second electron beam 4 formed when the cross section of the first electron beam 3 is triangular.

To form the second electron beam 4, the first pre-electron beam 1 may be emitted from the electron gun 10. The first pre-electron beam 1 may pass through the first aperture 102. Then, the second pre-electron beam 2 may pass through the second aperture 202, i.e., pass the first overlap region 204 of the first and second apertures 102 and 202, as described previously with reference to formation of the first electron beam 3.

Referring to FIGS. 1 and 8 through 11, the first overlap region 204 may partially overlap the third mask 300. Accordingly, a portion 5-1, 5-2, 7-1, or 7-2 of the second pre-electron beam 2 may be blocked by the third mask 300, thereby failing to' pass through the third mask 300. On the other hand, the other portion 6-1, 6-2, 8-1, or 8-2 of the second pre-electron beam 2, i.e., a portion not blocked by the third mask 300, may pass through the third mask 300. The portion 6-1, 6-2, 8-1, or 8-2 of the second pre-electron beam 2, which passes through the third mask 300, may define the second electron beam 4. It is noted that the second electron beam 4 is illustrated in FIG. 1, even though the third mask 300 is omitted therefrom.

For example, the second electron beam 4 may have a cross-sectional shape that overlaps an edge of the cross section of the first electron beam 3. That is, referring to FIGS. 8 and 9, when the cross section of the first electron beam 3 is square, the cross section of the second electron beam 4 may have the same shape as an edge of the square cross section of the first electron beam 3, e.g., a cross-section of a rotated “L.” In another example, as illustrated in FIGS. 10 and 11, when the cross section of the first electron beam 3 is triangular, the cross section of the second electron beam 4 may have the same shape as an edge of the triangular cross section of the first electron beam 3, e.g., a linear cross-section of a cross-section or a rotated “L.”

At least one side of a polygonal shape of the first overlap region 204 and at least one side of the third mask 300 may be parallel to each other. Accordingly, at least one side of the cross section of the second pre-electron beam 2 that passes through the first overlap region 204 may be parallel to at least one side of the third mask 300.

The third mask 300 may be made of an insulating material in order to eliminate the electromagnetic effect between itself and an electron beam.

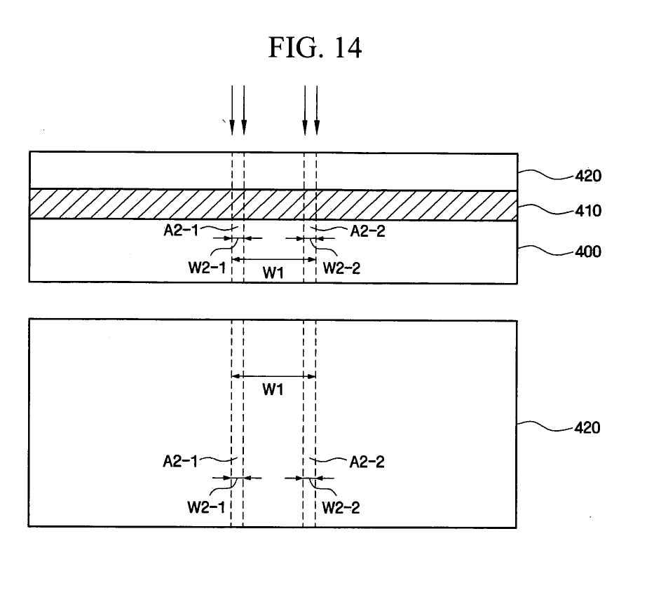

Hereinafter, a pattern forming method according to an exemplary embodiment will be described with reference to FIGS. 12 through 14. FIG. 12 illustrates a cross-sectional diagram of a substrate 400 on which a resist 400 is formed. FIG. 13 illustrates a diagram of irradiation of the first electron beam 3. FIG. 14 illustrates a diagram of irradiation of the second electron beam 4.

Referring to FIG. 12, a light-blocking film 410 and the resist 420 may be sequentially stacked on the substrate 400. The substrate 400 may be made of a transparent material, e.g., glass or quartz. In a subsequent process, the light-blocking film 410 may be changed into a light-blocking pattern having a predetermined critical dimension (CD) design value. The resist 420 may be developed to have a predetermined CD design value by irradiating an electron beam thereto. Accordingly, the light-blocking film 410 may be patterned. The resist 420 may be a negative resist, i.e., in which a region of the resist that is exposed to an electron beam remains after being developed, or a positive resist, i.e., in which a region of the resist that is exposed to an electron beam is removed after being developed.

Referring to FIG. 13, the first electron beam 3 may be irradiated to a first region A1 of the resist 420 in which a pattern needs to be formed. For example, the first region A1 may correspond to the first overlap region 240 or the second overlap region 260 described previously. Here, a width W1 of the first region A exposed to the first electron beam 3 may be determined by a predetermined CD design value, e.g., the width WI may be adjusted by rotating the first and second masks 100 and 200 when setting the first or second overlap regions 240 and 260.

Referring to FIG. 14, the second electron beam 4 may be additionally irradiated to second regions A2-1 and A2-2 which are defined along boundaries of the first region A1. For example, the second regions A2-1 and A2-2 may correspond to portion 6-1, 6-2, 8-1, or 8-2 described previously. Here, widths W2-1 and W2-2 of respective second regions A2-1 and A2-2 exposed to the second electron beam 4 may be smaller than the width W1 of the first region A1. That is, the second regions A2-1 and A2-2 may be narrower than the first region A1.

The second regions A2-1 and A2-2 may be located within the first region A1. Accordingly, the second electron beam 4 may additionally be irradiated along the boundaries of the first region A1, thereby forming an enhanced pattern.

The intensity of the second electron beam 4 may be higher than that of the first electron beam 3. Accordingly, a pattern that meets a predetermined CD design value may be formed in the light-blocking film 410 and the resist 420.

It is noted that conventionally an electron beam may be irradiated not only to a region of the resist 420 in which a pattern needs to be formed, e.g., the electron beam may be reflected off a surface of the light-blocking film 410, may be scattered after colliding with atoms of a resist material in the resist 420, may be reflected inside the resist 420 or off a surface of the resist 420, or may be reflected off the bottom surface of the objective lens 41 included in the electron beam writer. This, i.e., rescattering of the electron beam, may distort a predetermined CD design value, e.g., the linewidth of a circuit in a semiconductor.

Rescattering of an electron beam is related to the intensity of the electron beam and the area of a region to which the electron beam is irradiated. That is, the higher the intensity of the electron beam and the wider the region to which the electron beam is irradiated, the more the electron beam will be rescattered.

Therefore, according to example embodiments, the first electron beam 3 having a lower intensity than the second electron beam 4 may be irradiated to the first region A of the resist 420 which corresponds to a predetermined CD design value. Then, the second electron beam 4 having a higher intensity than the first electron beam 3 may be irradiated to the second regions A2-1 and A2-2 which are narrower than the first region A and are defined along the boundaries of the first region A1. If a pattern is formed according to example embodiments, rescattering of an electron beam may be minimized, which in turn, may reduce distortion of a predetermined CD design value, e.g., the linewidth of a circuit in a semiconductor. Further, blurring of an electron beam, i.e., caused by an electromagnetic force between electrons of the electron beam; may be prevented or substantially minimized.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A pattern forming method, comprising:
providing a resist;
irradiating a first electron beam to a first region of the resist; and
irradiating a second electron beam to a second region of the resist, the second region of the resist being defined along a boundary of the first region of the resist,
wherein the first electron beam has a first cross section having a polygonal shape, and the second electron beam has a second cross section having a polygonal shape.

2. The method as claimed in claim 1, wherein irradiating the first electron beam includes:
emitting a first pre-electron beam; and
passing the first pre-electron beam sequentially through a first mask having a first aperture and a second mask having a second aperture to form the first electron beam, an overlap region of the first aperture and the second aperture having a polygonal shape.

3. The method as claimed in claim 2, wherein the polygonal shape of the overlap region is a square or a triangle.

4. The method as claimed in claim 2, wherein irradiating the second electron beam includes:
emitting a second pre-electron beam; and
passing the second pre-electron beam sequentially through the first mask having the first aperture, the second mask having the second aperture, and a third mask to form the second electron beam, the third mask and the overlap region partially overlapping each other.

5. The method as claimed in claim 4, wherein at least one side of the polygonal shape of the overlap region and at least one side of the third mask are parallel to each other.

6. The method as claimed in claim 4, wherein the first through third masks are made of insulating materials.

7. The method as claimed in claim 1, wherein the second region of the resist is within the first region of the resist.

8. The method as claimed in claim 7, wherein the second region of the resist is narrower than the first region of the resist.

9. The method as claimed in claim 1, wherein irradiating the first and second electron beams includes irradiating the second electron beam at a higher intensity than the first electron beam.
